(19) United States
(12) Patent Application Publication
(10) Pub. No.: US 2026/0085423 A1
(43) Pub. Date: Mar. 26, 2026

(54) Levitating Magnet Deposition

(71) Applicant: Dexter Magnetic Technologies, Inc., Elk Grove Village, IL (US)

(72) Inventors: Emile Augustine, Elk Grove Village, IL (US); David Anderson, Elk Grove Village, IL (US); Ahmet Hirka, Elk Grove Village, IL (US); Nathaniel Sattler, Elk Grove Village, IL (US)

(73) Assignee: Dexter Magnetic Technologies, Inc., Elk Grove Village, IL (US)

(21) Appl. No.: 18/895,726

(22) Filed: Sep. 25, 2024

(51) Int. Cl. C23C 16/458

(52) U.S. Cl. CPC C23C 16/4583

(57) ABSTRACT

The present disclosure introduces an apparatus and related kit and method. The apparatus comprises a cooler, a spacer, and an orienter. The cooler comprises: a body having an internal passage for conducting a coolant through the body; and a superconductive insert positioned in a recess in an external surface of the body. The spacer rests on the cooler to set a levitation height of a magnetic element over the superconductive insert. The orienter has an opening to receive and orient the magnetic element at the levitation height relative to the superconductive insert.

### BACKGROUND OF THE DISCLOSURE

Magnetic elements utilized in, for example, devices implanted into the human body are coated for various reasons. During the coating process, the magnetic element is positioned on a fixture permitting the coating to be applied to all top, side, and bottom surfaces. However, small imperfections form around areas of contact between the magnetic element and the fixture. Such imperfections in the coating prevent the magnetic element from working as intended.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an apparatus comprising a cooler, a spacer, and an orienter. The cooler comprises: a body having an internal passage for conducting a coolant through the body; and a superconductive insert positioned in a recess in an external surface of the body. The spacer rests on the cooler to set a levitation height of a magnetic element over the superconductive insert. The orienter has an opening to receive and orient the magnetic element at the levitation height relative to the superconductive insert.

The present disclosure also introduces a method comprising: positioning a spacer on a cooler; then positioning an orienter on the spacer; then positioning an alignment fixture around the cooler, the spacer, and the orienter; and then positioning a magnetic element on the spacer within an opening of the orienter. The method then comprises, while conducting coolant past a superconductive insert of the cooler and thereby levitating the magnetic element: removing the alignment fixture from around the cooler, the spacer, and the orienter; removing the orienter from around the levitating magnetic element; removing the spacer from between the levitating magnetic element and the superconductive insert; and depositing a coating on all surfaces of the levitating magnetic element.

The present disclosure also introduces a kit comprising a cooler, a spacer, an orienter, and an alignment fixture. The cooler comprises: a body having an internal passage for conducting a coolant through the body; and a superconductive insert positioned in a recess in an external surface of the body. The spacer is for resting on the cooler to set a levitation height of a magnetic element over the superconductive insert. The orienter has an opening for receiving and orienting the magnetic element at the levitation height relative to the superconductive insert. The alignment fixture is configured to align the spacer and the orienter relative to the cooler. When the kit is assembled, conducting the coolant through the body causes the superconductive insert to levitate the magnetic element at a predetermined relative orientation during coating deposition of the levitating magnetic element.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic exploded view of at least a portion of an example implementation of a kit comprising an apparatus according to one or more aspects of the present disclosure.

FIG. 2 is a partial sectional side view of a portion of the apparatus shown in FIG. 1 in an intermediate stage of assembly within a deposition chamber according to one or more aspects introduced by the present disclosure

FIG. 3 is a schematic side view of a further portion of the apparatus shown in FIG. 2 in a subsequent stage of assembly according to one or more aspects introduced by the present disclosure.

FIG. 4 is a schematic side view of a further portion of the apparatus shown in FIG. 3 in a subsequent stage of assembly according to one or more aspects introduced by the present disclosure.

FIG. 5 is a partial sectional side view of a portion of the apparatus shown in FIGS. 1-4 during a deposition process according to one or more aspects introduced by the present disclosure.

FIG. 6 is a sectional view of a magnetic element coated according to one or more aspects introduced by the present disclosure.

FIG. 7 is a flow-chart diagram of at least a portion of an example implementation of a method according to one or more aspects introduced by the present disclosure.

FIG. 8 is a top view of at least a portion of an example implementation of apparatus according to one or more aspects introduced by the present disclosure.

FIG. 9 is a side view of the apparatus shown in FIG. 8.

FIG. 10 is a sectional view of the apparatus shown in FIGS. 8 and 9.

FIG. 11 is a sectional view of the apparatus shown in FIGS. 8-10.

FIG. 12 is a partial sectional side view of at least a portion of an example implementation of apparatus according to one or more aspects of the present disclosure.

FIG. 13 is a sectional view of a portion of the apparatus shown in FIG. 12 during a deposition process according to one or more aspects introduced by the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

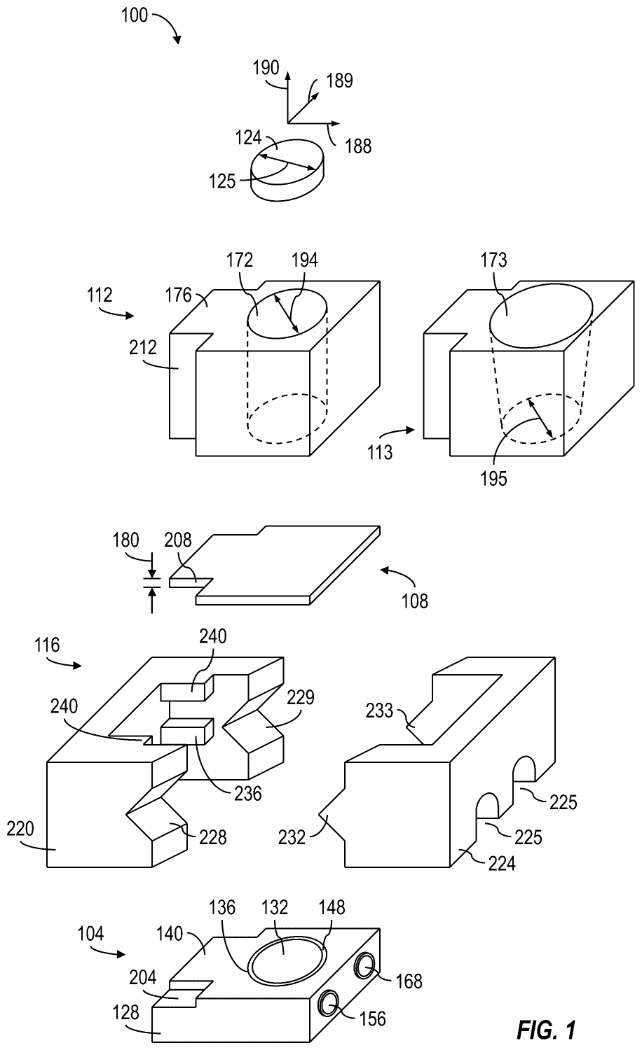

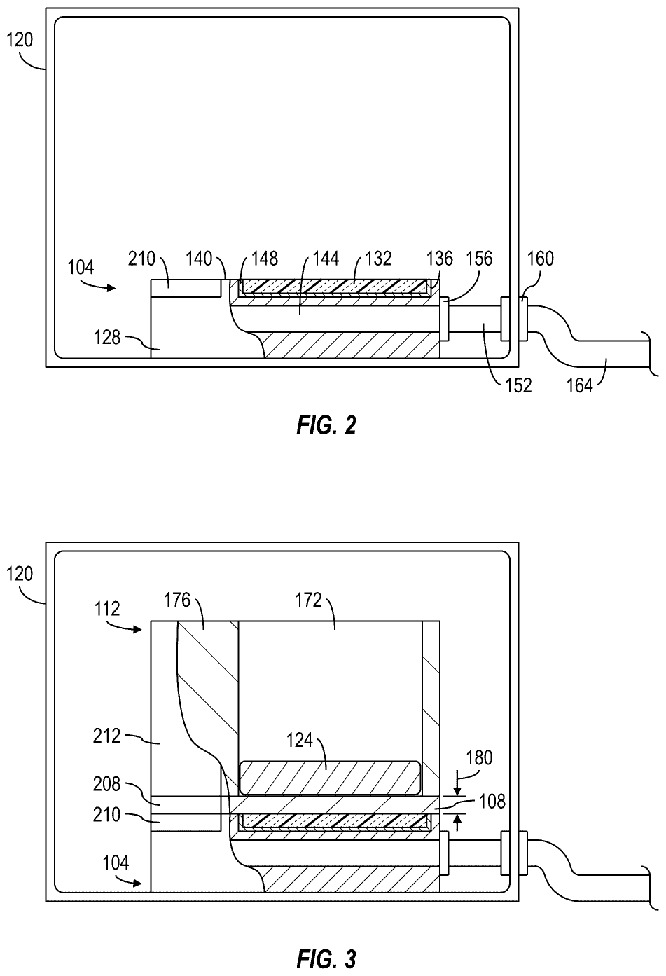

FIG. 1 is an exploded view of at least a portion of an example implementation of an apparatus 100 according to one or more aspects introduced by the present disclosure. The apparatus 100 comprises a cooler 104, a spacer 108, an orienter 112, and perhaps an alignment fixture 116. FIG. 2 is a partial sectional side view of a portion of the apparatus 100 in an intermediate stage of assembly within a deposition chamber 120 according to one or more aspects introduced by the present disclosure. After further assembly of the apparatus 100 within the deposition chamber 120, as described below with respect to FIGS. 3-5, the apparatus 100 may be utilized to levitate a magnetic element 124 for deposition of a coating on the magnetic element 124 within the deposition chamber 120 according to one or more aspects introduced by the present disclosure.

Referring to FIGS. 1 and 2, collectively, the cooler 104 comprises a body 128 and a superconductive insert 132 positioned in a recess 136 in an external surface 140 of the body 128. The body 128 also comprises an internal passage 144 for conducting coolant through the body 128. The internal passage 144 is sufficiently close to the superconductive insert 132 within the body 128 so that conductive heat transfer from the superconductive insert 132 through the body 128 to the coolant flowing within the internal passage 144 sufficiently cools the superconductive insert 132 to the critical temperature at which the superconductive insert 132 enters the superconducting state. For example, the cooler body 128 may primarily be formed from an oxygen-free, high thermal conductivity material (e.g., copper) and the coolant may be or comprise one or more cryogenic materials (e.g., liquid nitrogen). A thermal paste 148 may be utilized to fill interstitial space within the recess 136 and thereby aid in thermal contact and, thus, conductive heat transfer between the body 128 and the superconductive insert 132. The thermal paste 148 may be KRYONAUT EXTREME, APIEZON N GREASE, and/or other materials formulated to withstand cryogenic temperatures while improving thermal contact. The superconductive insert 132 may be formed from yttrium-barium-copper-oxide (YBCO) and/or other high-temperature superconducting (HTS) materials that permit the phenomenon known as flux pinning, in which the magnetic element 124 levitated above the superconductive insert 132 experiences a lateral and vertical restoring force that seeks to retain the initial position of the magnetic element 124 (i.e., the position of the magnetic element 124 when the superconductive insert 132 enters the superconducting state).

In FIG. 2, the cooler 104 has been positioned within the deposition chamber 120. An insulated metal conduit 152 connects an input connector 156 of the cooler 104 with a pass-through connector 160 of the deposition chamber 120. Another insulated conduit 164 connects the connector 160 to a coolant pump (not shown) operable to pump coolant through the conduits 164, 152 and the connectors 160, 156 to the internal passage 144 of the cooler body 128. Coolant is discharged from the internal passage 144 via an output connector 168, which is connected to other conduits and connectors (neither shown) for subsequent disposal and/or other handling of the discharged coolant.

FIG. 3 is a partial sectional side view of the apparatus 100 shown in FIG. 2 in a subsequent stage of assembly within the deposition chamber 120 according to one or more aspects introduced by the present disclosure. The following description refers to FIGS. 1 and 3, collectively.

In FIG. 3, the spacer 108 has been positioned on the cooler 104, the orienter 112 has been positioned on the spacer 108, and the magnetic element 124 has been positioned on the spacer 108 within an opening 172 of a body 176 the orienter 112. The spacer 108 has a thickness 180 equal to a predetermined levitation height 184 (see FIG. 5) such that positioning the magnetic element 124 on the spacer 108 positions the magnetic element 124 at the levitation height 184. The opening 172 in the orienter body 176 receives and orients the magnetic element 124 at the levitation height 184 relative to the superconductive insert 132. That is, in conjunction with gravity and the spacer 108 orienting the magnetic element 124 at the levitation height 184 over the superconductive insert 132, the orienter 112 orients the lateral position of the magnetic element 124 relative to the superconductive insert 132, including the pitch (about axis 188 in FIG. 1), roll (about axis 189), and yaw (about axis 190) of the magnetic element 124 relative to the superconductive insert 132. For example, the body opening 172 may be substantially cylindrical and have a diameter 194 not more than a few microns larger than an outer diameter 125 of the magnetic element 124. However, an alternate orienter 113 may have a funnel-shaped body opening 173 tapering downward to an inner diameter 195 not more than a few microns larger than the outer diameter 125 of the magnetic element 124. Different implementations of the magnetic element 124 of varying thickness may work between with different ones of the orienters 112, 113. Hereafter, reference to the orienter 112 is also applicable to the orienter 113.

During assembly, alignment features 204, 208, 212 may aid in the relative alignment of the corresponding cooler 104, spacer 108, and orienter 112. For example, the alignment features 204, 208, 212 may be identically sized cutouts that, when aligned, cause the magnetic element 124 to be centered over the superconductive insert 132 at the levitation height 184. However, an external alignment fixture may also be utilized to obtain the intended relative alignment of the spacer 108 and the orienter 112 over the cooler 104.

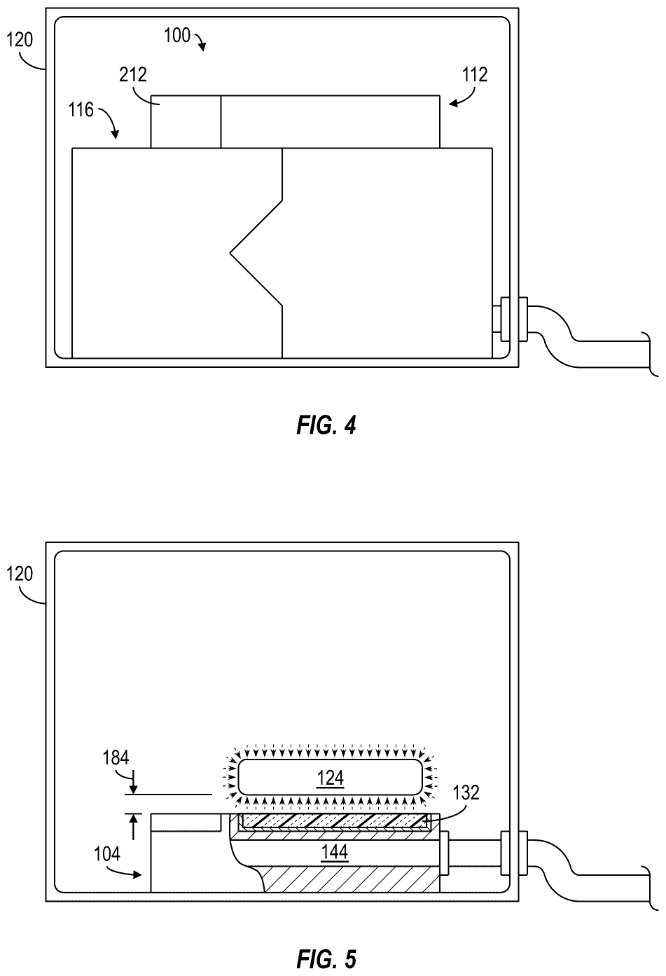

For example, FIG. 4 is a side view of the apparatus 100 assembled with the alignment FIG. 116 within the deposition chamber 120 according to one or more aspects introduced by the present disclosure. The following description refers to FIGS. 1 and 4, collectively.

The alignment fixture 116 may comprise first and second members 220, 224 configured to close around and, thereby, relatively align the cooler 104, the spacer 108, and the orienter 112. The members 220, 224 may comprise external alignment features 228, 232 configured to engage when the members 220, 224 are fully closed. Such alignment features 228, 232 may be configured to permit the members 220, 224 to be fully closed around the cooler 104, the spacer 108, and the orienter 112 in just a single configuration, thus removing uncertainty as to the intended orientation of the magnetic element 124 over the superconductive insert 132. For example, as most clearly observable in FIG. 1, the alignment feature 228 of the fixture member 220 may be a V-shaped concavity and the alignment feature 232 of the fixture member 224 may be a correspondingly V-shaped protrusion configured for seating within the alignment feature 232. As also depicted in FIG. 1, the alignment feature 228 of the fixture member 220 may be tapered radially outward and the alignment feature 232 of the fixture member 224 may be correspondingly tapered radially inward, such that the alignment features 228, 232 may only fully engage when the fixture members 220, 224 are in a predetermined relative configuration, whereas another alignment feature 229 of the fixture member 220 may be a V-shaped concavity that is tapered radially inward and another alignment feature 233 of the fixture member 224 may be a correspondingly V-shaped protrusion correspondingly tapered radially outward such that the alignment features 229, 233 fully engage just when the fixture members 220, 224 are in the predetermined relative configuration. However, the mating concavities 228, 229 and protrusions 232, 233 may have shapes other than as depicted in FIG. 1, such an in implementations in which the concave features 228, 229 and the correspondingly convex features 232, 233 are curvilinearly shaped and/or otherwise shaped yet still engaging (e.g., meshing) in just one predetermined relative configuration of the alignment fixture members 220, 224. The fixture member 224 may also comprise cutouts 225 configured to fit around the connectors 156, 168 and/or corresponding conduits, which may also aid in the alignment and meshing engagement of the fixture members 220, 224 so as to align the spacer 108 and the orienter 112 in predetermined positions relative to the cooler 104.

The alignment fixture members 220, 224 may also comprise internal alignment features configurated to aid in the alignment of the spacer 108 and/or the orienter 112 relative to the cooler 104, thereby aligning the magnetic element 124 relative to the superconductive insert 132. For example, first alignment features 236 of the alignment fixture member 220 may be received within and/or otherwise mesh with the recesses and/or other alignment features 204 of the cooler 104, so as to align the alignment fixture 116 relative to the cooler 104. The first alignment feature 236 may also be received within and/or otherwise mesh with the alignment features 208 of the spacer 108, so as to align the spacer 108 to the alignment fixture 116 and, thus, the cooler 104. Second alignment fixtures 240 of the alignment fixture member 220 may similarly be received within and/or otherwise mesh with the recesses and/or other alignment features 212 of the orienter 112 and/or the alignment features 208 of the spacer 108, so as to align the orienter 112 and/or the spacer 108 to the cooler 104.

After the spacer 108, the orienter 112, the magnetic element 124, and perhaps the alignment fixture 116 are aligned relative to the cooler 104, coolant may be pumped through the internal passage 144 to cool the superconductive insert 132 to the critical temperature at which the superconductive insert 132 enters the superconductive state, thereby pinning the magnetic element 124 in the intended position, as depicted in FIGS. 3 and/or 4. Thereafter, as depicted in FIG. 5, the members 220, 224 of the alignment fixture 116 may be disassembled (separated) and removed from the deposition chamber 120, the orienter 112 may be lifted off the spacer 108 and removed from the deposition chamber 120, and the spacer 108 may be slid out from between the magnetic element 124 and the cooler 104. The magnetic element 124 will continue to levitate at the levitation height 184 over the superconductive insert 132 as long as coolant continues to be pumped through the internal passage 144 so that the superconductive insert 132 remains at or below the critical superconducting temperature. During this time, the deposition chamber 120 may be utilized to evenly coat the entireties of the external surfaces of the magnetic element 124 via chemical vapor deposition (CVD), physical vapor deposition (PVD), atomic layer deposition (ALD), and/or other thin-film deposition processes.

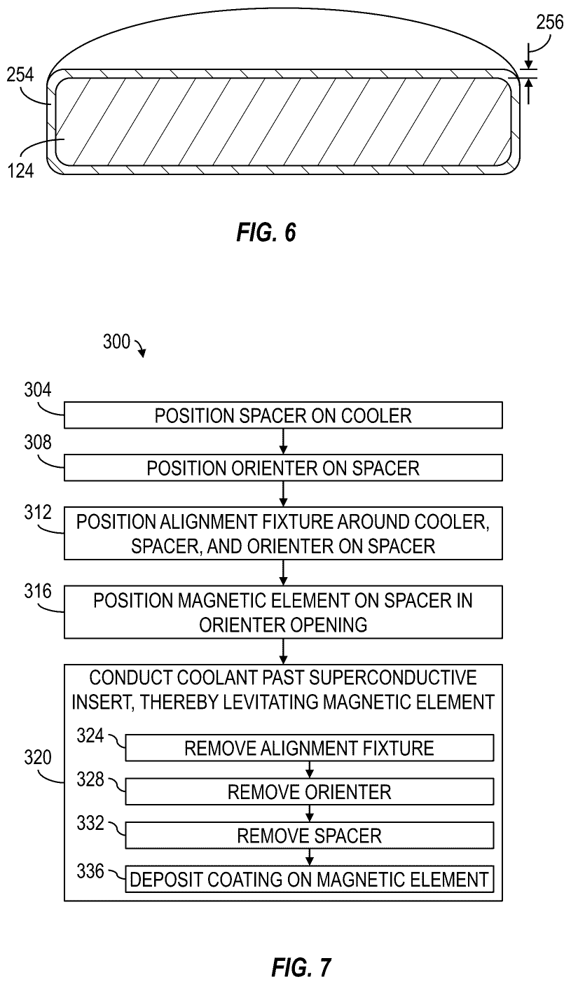

For example, FIG. 6 depicts the resulting magnetic element 124 with an even, continuous coating 254 covering the entirety of the external surfaces of the magnetic element 124. Examples of the coating 254 include 0.1-50 microns of parylene, 1-7 microns of titanium nitride, 0.3-0.6 microns of gold, and 10-100 microns of polytetrafluoroethylene (PTFE). However, other thicknesses of these and other materials are also within the scope of the present disclosure. Moreover, because the coating 254 is applied to the entireties of the external surfaces of the magnetic element 124 by utilizing one or more aspects introduced herein, the coating thickness 256 may vary by less than 5-10% at different external locations on the magnetic element 124.

FIG. 7 is a flow-chart diagram of at least a portion of an example implementation of a deposition method 300 according to one or more aspects introduced by the present disclosure. The method 300 is described below with continued reference to the components described above with respect to FIGS. 1-6. However, implementations of the method 300 utilizing components other than as depicted in FIGS. 1-6 are also contemplated as being within the scope of the present disclosure.

The method 300 comprises positioning 304 a spacer 108 on a cooler 104, such as within a deposition chamber 120 and/or other thin-film deposition tool. An orienter 112 is then positioned 308 on the spacer 108, and then an alignment fixture 116 is positioned 312 around the cooler 104, the spacer 108, and the orienter 112. A magnetic element 124 is then positioned 316 on the spacer 108 within an opening 172 of the orienter 112. Then, while conducting 320 coolant past a superconductive insert 132 of the cooler 104 and thereby levitating the magnetic element 124: removing 324 the alignment fixture 116 from around the cooler 104, the spacer 108, and the orienter 112; removing 328 the orienter 112 from around the levitating magnetic element 124; removing 332 the spacer 108 from between the levitating magnetic element 124 and the superconductive insert 132; and depositing 336 a coating 254 on all surfaces of the levitating magnetic element 124.

As described above, the cooler 104 comprises a body 128 having an internal passage 144 proximate the superconductive insert 132. Thus, conducting 320 the coolant past the superconductive insert 132 comprises conducting 320 the coolant through the passage 144.

As also described above, the spacer 108 has a thickness 180 equal to a predetermined levitation height 184, such that positioning 316 the magnetic element 124 on the spacer 108 positions the magnetic element 124 at the levitation height 184. Positioning 316 the magnetic element 124 within the orienter opening 172 orients lateral position, pitch, roll, and yaw of the magnetic element 124 relative to the superconductive insert 132.

As depicted in FIGS. 1-5, positioning 312 the alignment fixture 116 around the cooler 104, the spacer 108, and the orienter 112 orients the cooler 104, the spacer 108, and the orienter 112 in predetermined relative positions. For example, positioning 312 the alignment fixture 116 around the cooler 104, the spacer 108, and the orienter 112 may comprise engaging a corresponding feature 204, 208, 212 of each of the cooler 104, the spacer 108, and the orienter 112 within one or more corresponding features 236, 240 of the alignment fixture 116 to thereby align and/or otherwise position the cooler 104, the spacer 108, the orienter 112, and the alignment fixture 116 in a predetermined relative orientation.

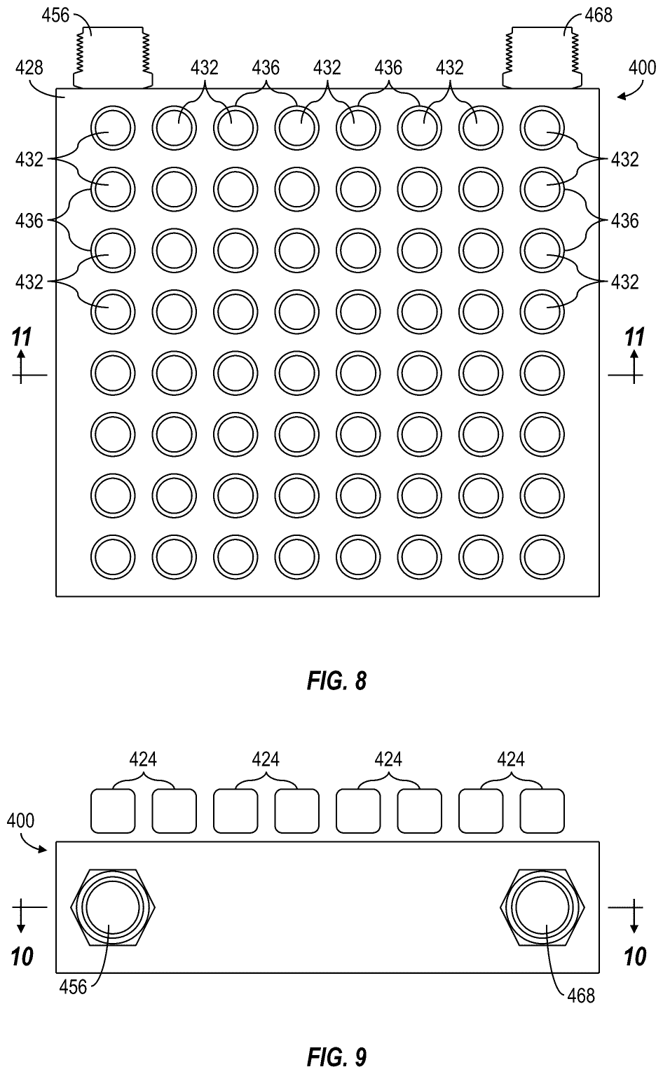

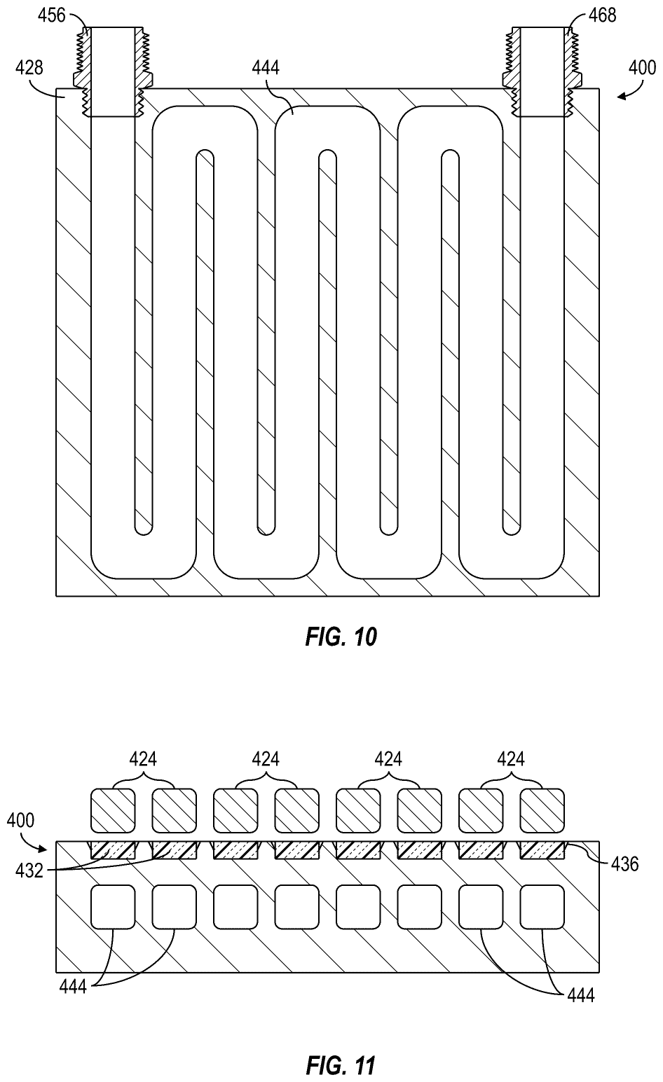

The method 700 depicted in FIG. 7 and/or other aspects described above are also adaptable for depositing a coating on a plurality of levitated magnetic elements simultaneously. For example, FIG. 8 is a top view of at least a portion of another example implementation of the cooler 104 shown in FIGS. 1-5 according to one or more aspects introduced by the present disclosure, the additional implementation designated in FIG. 8 by reference number 404. FIG. 9 is a side view of the cooler 404, as well as a plurality of magnetic elements 424 levitating above the cooler 404. FIG. 10 is a sectional view of the cooler 404 taken along the section lines depicted in FIG. 9. FIG. 11 is a sectional view of the cooler 404 taken along the section lines depicted in FIG. 8, as well as the plurality of levitating magnetic elements 424. The cooler 404 and magnetic elements 424 depicted in FIGS. 8-11 are analogous to (if not the same as) the cooler 104 and the magnetic element 124 depicted in FIGS. 1-5, except as described below. Thus, the above-described aspects of the cooler 104 and the magnetic element 124 are applicable or readily adaptable to the cooler 404 and the magnetic elements 424, respectively. The following description refers to FIGS. 8-11.

The cooler 404 comprises a body 428 and a plurality of superconductive inserts 432 each positioned in a corresponding one of a plurality of recesses 436 in an external surface 440 of the body 428. The body 428 also comprises an internal passage 444 for conducting coolant through the body 428 via input and output connectors 456, 468. The internal passage 444 follows a serpentine path, best perceived in FIG. 10, so as to closely pass each of the superconductive inserts 432 and thereby facilitate conductive heat transfer from the superconductive inserts 432 through the body 428 to coolant flowing within the internal passage 444. A thermal paste (not shown) may be utilized to fill interstitial space within the recesses 436 and thereby aid in thermal contact and, thus, conductive heat transfer to the body 428 from the superconductive inserts 432.

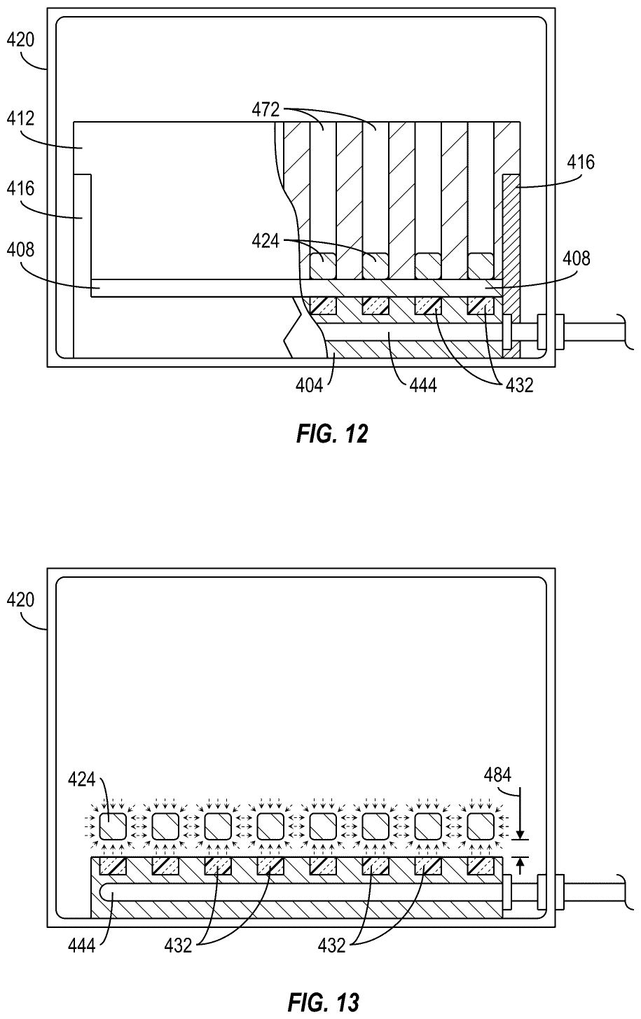

In FIG. 12, the cooler 404 has been positioned in a deposition chamber 420. A spacer 408 has been positioned on the cooler 404, an orienter 412 has been positioned on the spacer 408, the magnetic elements 424 have been positioned on the spacer 408 within openings 472 of the orienter 412, and an alignment fixture 416 has been placed around the cooler 404, the spacer 408, and the orienter 412. The spacer 408, the orienter 412, and the alignment fixture 416 are analogous to (if not the same as) the spacer 108, the orienter 112, and the alignment fixture 116 depicted in FIGS. 1-5, except as described below. Thus, the above-described aspects of the spacer 108, the orienter 112, and the alignment fixture 116 are applicable or readily adaptable to the spacer 408, the orienter 412, and the alignment fixture 416, respectively.

The spacer 408 has a thickness equal to the predetermined levitation height 484 (see FIG. 14) such that positioning the magnetic elements 424 on the spacer 408 positions the magnetic elements 424 at the levitation height 484. The openings 472 in the orienter 412 receive and orient the magnetic elements 424 at the levitation height 484 relative to the superconductive inserts 432. That is, in conjunction with gravity and the spacer 408 orienting the magnetic elements 424 at the levitation height 484 over the superconductive inserts 432, the orienter 412 orients the lateral position of each magnetic element 424 relative to the underlying superconductive insert 432, including the pitch, roll, and yaw of the magnetic element 424 relative to the underlying superconductive insert 432.

After the spacer 408, the orienter 412, the magnetic elements 424, and perhaps the alignment fixture 416 are aligned relative to the cooler 404, coolant may be pumped through the internal passage 444 to cool the superconductive inserts 432 to the critical temperature at which the superconductive inserts 432 enter the superconductive state, thereby pinning the magnetic elements 424 in the intended position, as depicted in FIG. 13. Thereafter, the alignment fixture 416 may be disassembled (separated) and removed from the deposition chamber 420, the orienter 412 may be lifted off the spacer 408 and removed from the deposition chamber 420, and the spacer 408 may be removed from between the magnetic elements 424 and the cooler 404. The magnetic elements 424 will continue to levitate at the levitation height 484 over the superconductive inserts 432 as long as coolant continues to be pumped through the internal passage 444 so that the superconductive inserts 432 remain at or below the critical superconducting temperature. During this time, the deposition chamber 420 may be utilized to evenly coat the entireties of the external surfaces of the magnetic elements 424 via CVD, PVD, ALD, and/or other thin-film deposition processes.

The shape of the above-described magnetic elements 124, 424 may vary within the scope of the present disclosure, such as the generally disc-shaped magnetic elements 124 depicted in FIGS. 1-6 and the generally cube-shaped magnetic elements 424 depicted in FIGS. 9 and 11-13. However, otherwise shaped magnetic elements are also within the scope of the present disclosure. The major dimensions of each magnetic element may be within the range of 1-10 millimeters, although other dimensions are also within the scope of the present disclosure.

In view of the entirety of the present disclosure, including the figures and the claims, a person having ordinary skill in the art will readily recognize that the present disclosure introduces an apparatus comprising a cooler, a spacer, and an orienter. The cooler comprises: a body having an internal passage for conducting a coolant through the body; and a superconductive insert positioned in a recess in an external surface of the body. The spacer rests on the cooler to set a levitation height of a magnetic element over the superconductive insert.

The orienter has an opening to receive and orient the magnetic element at the levitation height relative to the superconductive insert.

The orienter may orient lateral position, pitch, roll, and yaw of the magnetic element relative to the superconductive insert.

The apparatus may further comprise an alignment fixture configured to align the spacer and the orienter relative to the cooler.

In an example implementation, the alignment fixture comprises a plurality of members configured to be disassembled after the magnetic element is levitated by the superconductive insert.

In an example implementation, the cooler comprises a first feature, the alignment fixture comprises a second feature, and the first and second features correspondingly engage to position the cooler and the alignment fixture in a predetermined relative orientation. A first one of the first and second features may be a recess, and a second one of the first and second features may be a protrusion seated in the recess when the cooler and the alignment are in the predetermined relative orientation. The alignment fixture may comprises a third feature, the spacer may comprise a fourth feature, and the third and fourth features may correspondingly engage to position the alignment fixture and the spacer in a predetermined orientation relative to the cooler. In an example implementation, the orienter may comprise a fifth feature, and the fourth and fifth features may correspondingly engage to position the alignment fixture and the orienter in a predetermined orientation relative to the cooler and the spacer. In another example implementation, the alignment fixture may comprise a fifth feature, the orienter may comprise a sixth feature, and the fifth and sixth features may correspondingly engage to position the alignment fixture and the orienter in a predetermined orientation relative to the cooler and the spacer.

The superconductive insert may be formed of a high-temperature superconductive material. The material may be yttrium barium copper oxide.

The present disclosure also introduces a method comprising: positioning a spacer on a cooler; then positioning an orienter on the spacer; then positioning an alignment fixture around the cooler, the spacer, and the orienter; and then positioning a magnetic element on the spacer within an opening of the orienter. The method then comprises, while conducting coolant past a superconductive insert of the cooler and thereby levitating the magnetic element: removing the alignment fixture from around the cooler, the spacer, and the orienter; removing the orienter from around the levitating magnetic element; removing the spacer from between the levitating magnetic element and the superconductive insert; and depositing a coating on all surfaces of the levitating magnetic element.

The cooler may comprise a body having an internal passage proximate the superconductive insert, and conducting the coolant past the superconductive insert may comprise conducting the coolant through the passage.

The spacer may have a thickness equal to a predetermined levitation height such that positioning the magnetic element on the spacer positions the magnetic element at the levitation height.

Positioning the magnetic element within the orienter opening may orient lateral position, pitch, roll, and yaw of the magnetic element relative to the superconductive insert.

Positioning the alignment fixture around the cooler, the spacer, and the orienter may orient the cooler, the spacer, and the orienter in predetermined relative positions.

Depositing the coating may be via chemical vapor deposition.

The coating may be parylene, titanium nitride, gold, or PTFE.

Positioning the alignment fixture around the cooler, the spacer, and the orienter may comprise engaging a feature of each of the cooler, the spacer, and the orienter within one or more corresponding features of the alignment fixture to thereby position the cooler, the spacer, the orienter, and the alignment fixture in a predetermined relative orientation.

The present disclosure also introduces a kit comprising a cooler, a spacer, an orienter, and an alignment fixture. The cooler comprises: a body having an internal passage for conducting a coolant through the body; and a superconductive insert positioned in a recess in an external surface of the body. The spacer is for resting on the cooler to set a levitation height of a magnetic element over the superconductive insert. The orienter has an opening for receiving and orienting the magnetic element at the levitation height relative to the superconductive insert. The alignment fixture is configured to align the spacer and the orienter relative to the cooler. Conducting the coolant through the body causes the superconductive insert to levitate the magnetic element at a predetermined relative orientation during coating deposition of the levitating magnetic element.

The foregoing outlines features of several embodiments so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the embodiments introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to comply with 37 C.F.R. § 1.72(b) to permit the reader to quickly ascertain the nature of the technical disclosure. It is submitted with the understanding that it will not be used to interpret or limit the scope or meaning of the claims.

1. An apparatus, comprising:
a cooler, comprising:
a body having an internal passage for conducting a coolant through the body; and
a superconductive insert positioned in a recess in an external surface of the body;
a spacer resting on the cooler to set a levitation height of a magnetic element over the superconductive insert; and
an orienter having an opening to receive and orient the magnetic element at the levitation height relative to the superconductive insert.

2. The apparatus of claim 1 wherein the orienter orients lateral position, pitch, roll, and yaw of the magnetic element relative to the superconductive insert.

3. The apparatus of claim 1 further comprising an alignment fixture configured to align the spacer and the orienter relative to the cooler.

4. The apparatus of claim 3 wherein the alignment fixture comprises a plurality of members configured to be disassembled after the magnetic element is levitated by the superconductive insert.

5. The apparatus of claim 3 wherein:
the cooler comprises a first feature;
the alignment fixture comprises a second feature; and
the first and second features correspondingly engage to position the cooler and the alignment fixture in a predetermined relative orientation.

6. The apparatus of claim 5 wherein:
a first one of the first and second features is a recess; and
a second one of the first and second features is a protrusion seated in the recess when the cooler and the alignment fixture are in the predetermined relative orientation.

7. The apparatus of claim 5 wherein:
the alignment fixture comprises a third feature;
the spacer comprises a fourth feature; and
the third and fourth features correspondingly engage to position the alignment fixture and the spacer in a predetermined orientation relative to the cooler.

8. The apparatus of claim 7 wherein:
the orienter comprises a fifth feature; and
the fourth and fifth features correspondingly engage to position the alignment fixture and the orienter in a predetermined orientation relative to the cooler and the spacer.

9. The apparatus of claim 7 wherein:
the alignment fixture comprises a fifth feature;
the orienter comprises a sixth feature; and
the fifth and sixth features correspondingly engage to position the alignment fixture and the orienter in a predetermined orientation relative to the cooler and the spacer.

10. The apparatus of claim 1 wherein the superconductive insert is formed of a high-temperature superconductive material.

11. The apparatus of claim 10 wherein the high-temperature superconductive material is yttrium barium copper oxide.

12. (Withdrawn, Currently Amended) A method, comprising:
positioning a spacer on a cooler;
then positioning an orienter on the spacer;
then positioning an alignment fixture around the cooler, the spacer, and the orienter;
then positioning a magnetic element on the spacer within an opening of the orienter; and
then, while conducting coolant past a superconductive insert of the cooler and thereby levitating the magnetic element:
removing the alignment fixture from around the cooler, the spacer, and the orienter;
removing the orienter from around the magnetic element;
removing the spacer from between the magnetic element and the superconductive insert; and
depositing a coating on all surfaces of the magnetic element.

13. (Withdrawn, Currently Amended) The method of claim 12 wherein:
the cooler comprises a body having an internal passage proximate the superconductive insert; and
conducting the coolant past the superconductive insert comprises conducting the coolant through the internal passage.

14. The method of claim 12 wherein the spacer has a thickness equal to a levitation height such that positioning the magnetic element on the spacer positions the magnetic element at the levitation height.

15. The method of claim 12 wherein positioning the magnetic element on the spacer orients lateral position, pitch, roll, and yaw of the magnetic element relative to the superconductive insert.

16. The method of claim 12 wherein positioning the alignment fixture around the cooler, the spacer, and the orienter orients the cooler, the spacer, and the orienter in predetermined relative positions.

17. The method of claim 12 wherein depositing the coating is via chemical vapor deposition.

18. The method of claim 12 wherein the coating is parylene.

19. The method of claim 12 wherein positioning the alignment fixture around the cooler, the spacer, and the orienter comprises engaging a feature of each of the cooler, the spacer, and the orienter within one or more corresponding features of the alignment fixture to thereby position the cooler, the spacer, the orienter, and the alignment fixture in a predetermined relative orientation.

20. A kit, comprising:
a cooler, comprising:
a body having an internal passage for conducting a coolant through the body; and
a superconductive insert positioned in a recess in an external surface of the body;
a spacer for resting on the cooler to set a levitation height of a magnetic element over the superconductive insert;
an orienter having an opening for receiving and orienting the magnetic element at the levitation height relative to the superconductive insert; and
an alignment fixture configured to align the spacer and the orienter relative to the cooler;
wherein conducting the coolant through the body causes the superconductive insert to levitate the magnetic element at a predetermined relative orientation during coating deposition of the magnetic element.
